(19) United States
(12) Patent Application Publication
(10) Pub. No.: US 2014/0369747 A1
(43) Pub. Date: Dec. 18, 2014

(54) PANEL ASSEMBLY

(71) Applicants: HON HAI PRECISION INDUSTRY CO., LTD., New Taipei (TW); HONG FU JIN PRECISION INDUSTRY (ShenZhen) CO., LTD ., Shenzhen (CN)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD ., Shenzhen (CN)

(21) Appl. No.: 14/198,605

(22) Filed: Mar. 6, 2014

(30) Foreign Application Priority Data
Jun. 17, 2013 (CN) 2013102369868

(51) Int. Cl. H05K 7/14; F16B 5/00

(52) U.S. Cl. CPC H05K 7/1488; F16B 5/00
USPC 403/376

(57) ABSTRACT

A panel assembly includes a panel and an installation module for securing an end of the panel to an enclosure. The installation module includes a positioning member secured to the panel, an operation member including a blocking portion is slidably mounted in the positioning member, and a mounting member slidably mounted in the positioning member and defining a mounting slot. The operation member is slidably positioned in an unlocked position, where the blocking portion is aligned with the mounting slot, and the mounting member is slidable relative to the panel to be engaged in a locking hole defined in the enclosure. In a locked position, the blocking portion staggers the mounting slot, and the mounting member is blocked by the blocking portion and prevented from sliding relative to the panel, so as to secure the panel assembly to the chassis.

### FIELD

Embodiments of the present disclosure relate to panel assemblies, and particularly to a panel assembly used in a server.

### BACKGROUND

In many servers, a first end of a panel assembly is rotatably mounted to an enclosure of each server. However, a second end of the panel assembly is generally secured to the enclosure by screws, which requires a screw driver to secure the screws to the panel assembly. Disassembly or reassembly of the panel assembly can be tedious and inconvenient. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a panel assembly.

FIG. 2 is an isometric view of an installation module of the panel assembly of FIG. 1.

FIG. 3 is similar to FIG. 2, but viewed from a different aspect.

FIG. 4 is an assembled, isometric view of the panel assembly of FIG. 1, showing an operation member in a locked position.

FIG. 5 is an enlarged view of a circled portion V of FIG. 4.

FIG. 6 is similar to FIG. 4, but viewed from a different aspect.

FIG. 7 is another assembled, isometric view of the panel assembly of FIG. 1, but showing the operation member in an unlocked position.

FIG. 8 is similar to FIG. 7, but viewed from a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

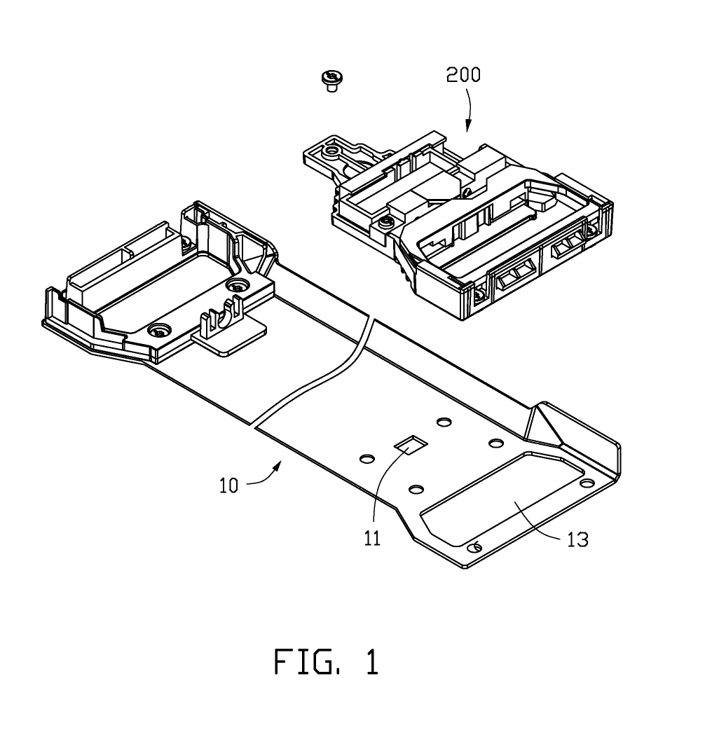

FIG. 1 shows one embodiment of a panel assembly. The panel assembly includes a panel 10 and an installation module 200.

The panel 10 defines a through hole 11 and an opening 13. In one embodiment, the through hole 11 is rectangular.

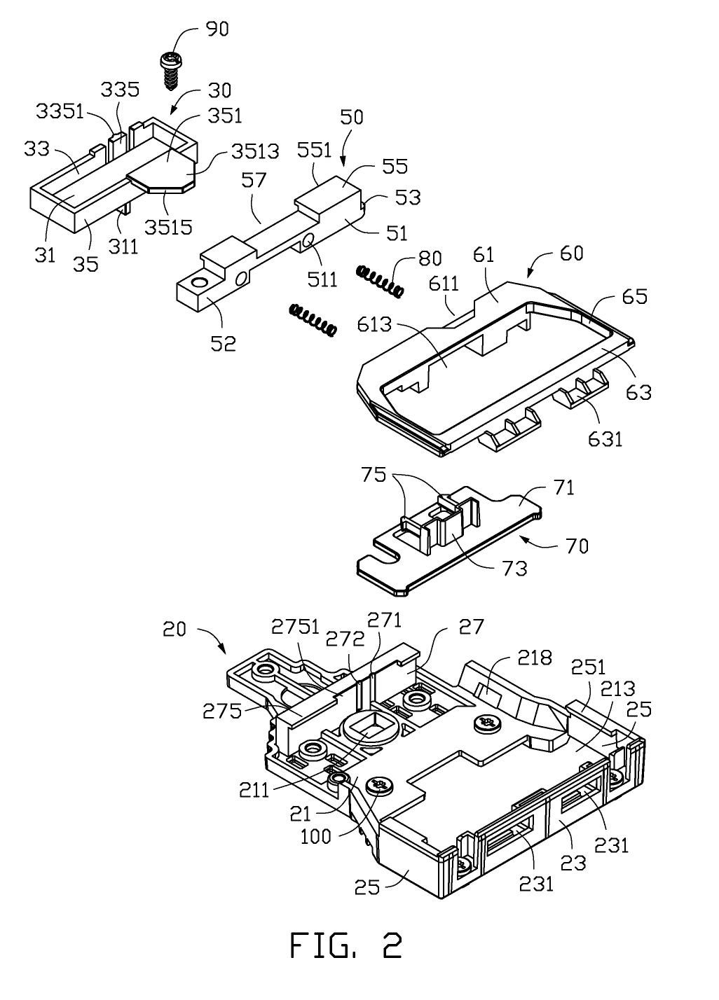

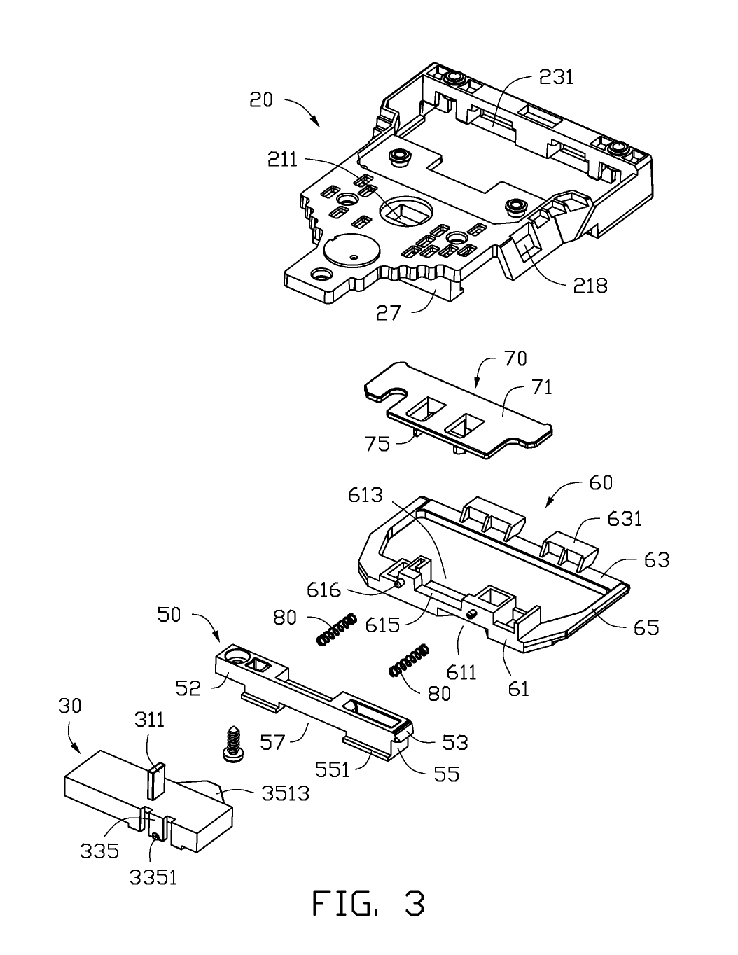

FIG. 2 and FIG. 3 show the installation module 200 includes a positioning member 20, an operation member 30, a limiting member 50, a mounting member 60, and a sliding member 70.

The positioning member 20 includes a bottom plate 21, a rear plate 23, two side plates 25, and a positioning plate 27 extending from the bottom plate 21. In one embodiment, the bottom plate 21 is substantially perpendicular to the rear plate 23, the positioning plate 27 is substantially perpendicular to the bottom plate 21, and the positioning plate 27 is substantially parallel to the rear plate 23. The bottom plate 21 defines a positioning hole 211 and a slot 213. The positioning hole 211 corresponds to the through hole 11, and the slot 213 corresponds to the opening 13. The rear plate 23 defines two installation slots 231. A side flange 251 extends from a top edge of each side plate 25 towards another side plate 25. The positioning plate 27 defines a first positioning slot 271 and a second positioning slot 272. In one embodiment, an extending direction of the first positioning slot 271 is substantially parallel to an extending direction of the second positioning slot 272, and each extending direction of the first positioning slot 271 and the second positioning slot 272 is substantially perpendicular to the bottom plate 21. A positioning flange 275 extends from a top edge of the positioning plate 27. The positioning flange 275 defines a cutout 2751. A side of the positioning member 20 defines a limiting hole 218.

The operation member 30 includes an operation plate 31, a first flange 33 extending from a first edge of the operation plate 31, and a second flange 35 extending from a second edge of the operation plate 31. In one embodiment, the first flange 33 is substantially parallel to the second flange 35 and substantially perpendicular to the operation plate 31. An operation piece 311 extends from a top surface of the operation plate 31. The first flange 33 and the second flange 35 extend from a bottom surface of the operation plate 31. The first flange 33 defines two nicks 331, and the first flange 33 includes an elastically deformable positioning piece 335 between the two nicks 331. A positioning protrusion 3351 protrudes from the positioning piece 335. A blocking portion 352 extends from a top edge of the second flange 35 away from the first flange 33. The blocking portion 351 includes a blocking piece 3513. The blocking piece 3513 includes a blocking plane 3515. In one embodiment, a cross section of the blocking piece 3513 is trapeziform, and the blocking plane 3515 is a slanted plane of the trapeziform.

The limiting member 50 includes a base 51, a positioning block 53 extending from a first side of the base 51, and an installation block 52 extending from a second side of the base 51. The positioning block 53 can be inserted into the limiting hole 218. The installation block 52 can be secured to the bottom plate 21. The base 51 defines two receiving holes 511, and the receiving holes 511 do not extend through the base 51. Two limiting blocks 55 extend from the base 51. A sliding slot 57 is defined between the two limiting blocks 55. A limiting flange 551 extends from a top edge of each limiting block 55.

The mounting member 60 includes a mounting portion 61, a mounting wall 63, and two sidewalls 65 connected to the mounting portion 61 and the mounting wall 63. The mounting portion 61 defines a limiting slot 611 and a mounting slot 613. A resisting block 615 is located in the mounting slot 613. A mounting post 616 is located on the mounting portion 61. Two mounting blocks 631 extend from the mounting wall 63 away from the mounting portion 61.

The sliding member 70 includes a sliding plate 71, a resisting portion 73 extending from the sliding plate 71, and two elastically deformable hooks 75 extending from the resisting portion 73.

The installation module 200 further includes two resilient members 80. In one embodiment, each resilient member 70 is a compression spring.

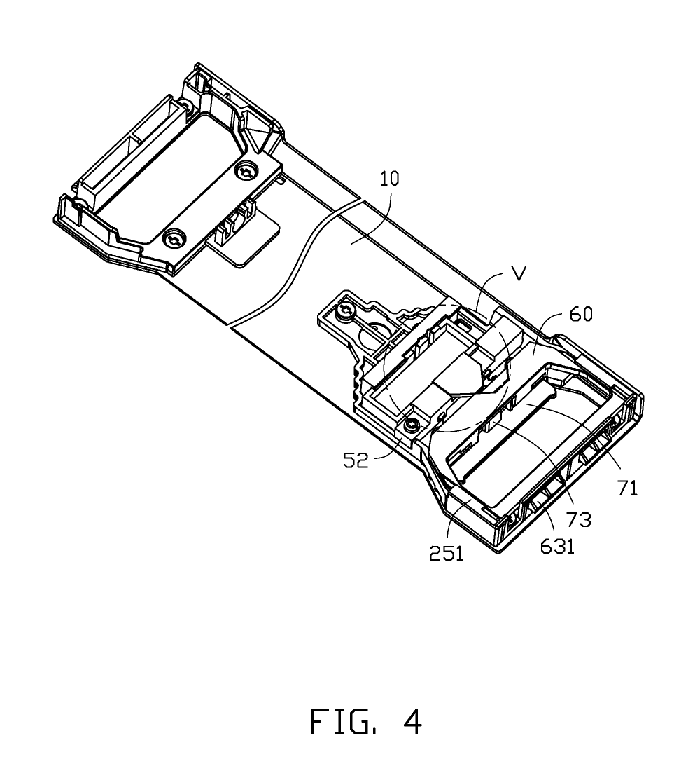

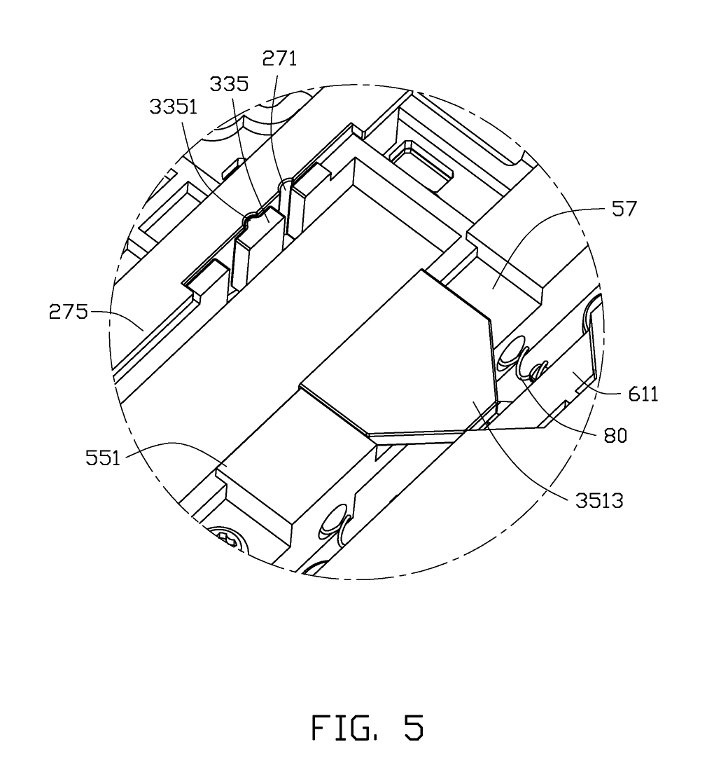

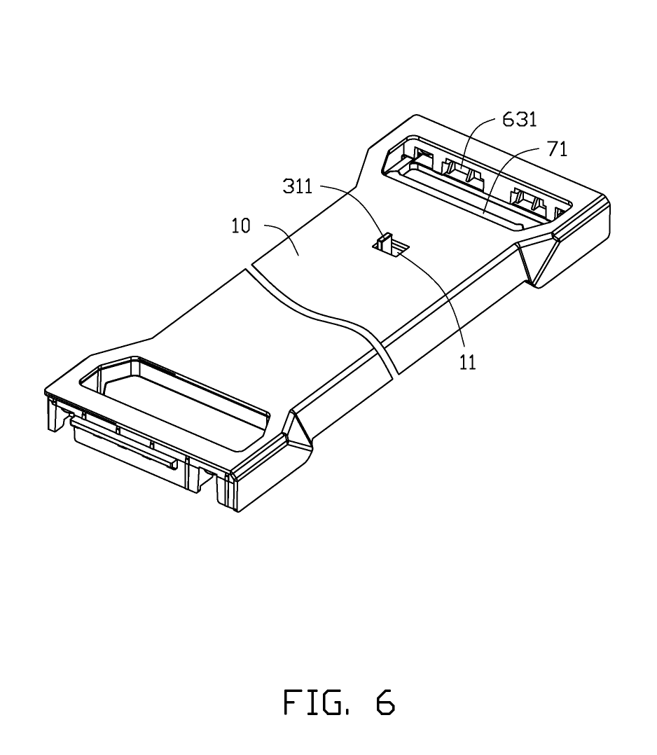

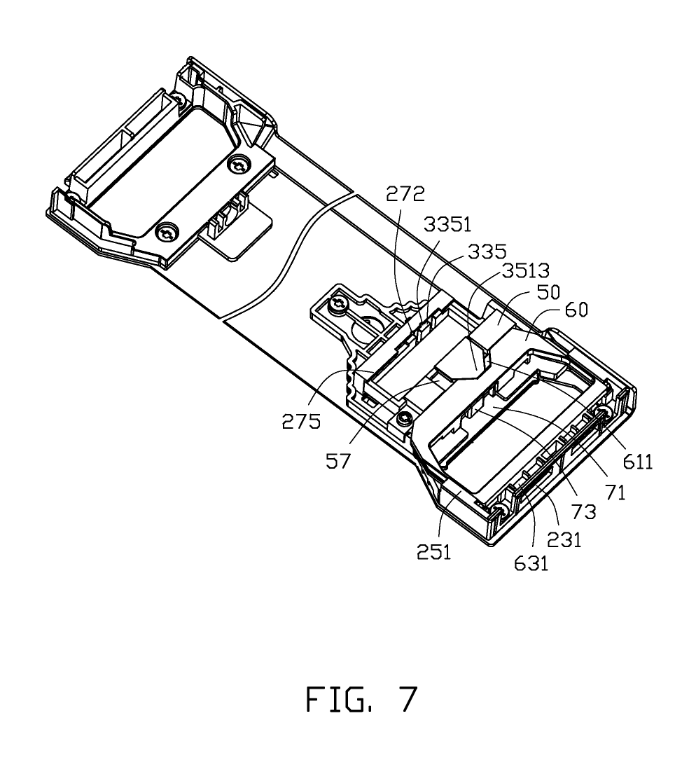

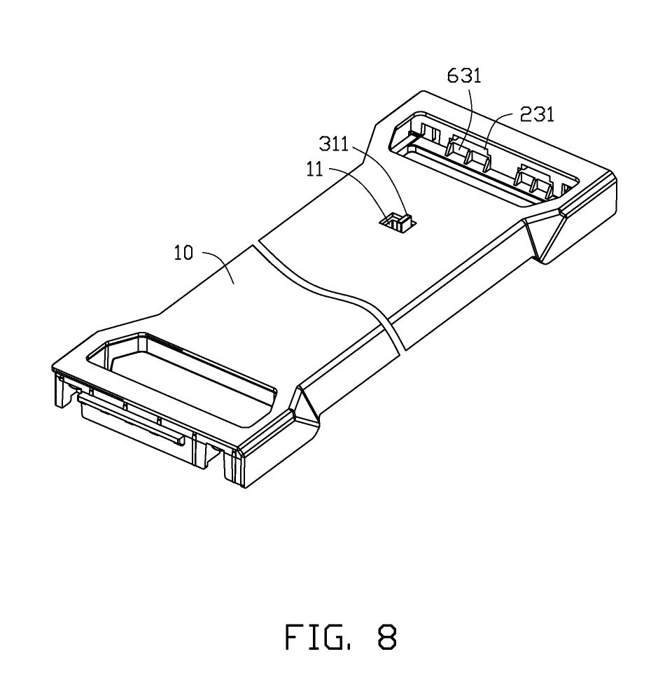

FIGS. 4-8 show that in assembly, the positioning member 20 is secured to the panel 10 by a plurality of first screws 100. The positioning hole 211 is aligned with the through hole 11, and the slot 213 is aligned with the opening 13. The operation member 30 is placed between the positioning flange 275 and the bottom plate 21. The operation piece 311 extends out of the positioning hole 211 and the through hole 11, and the positioning protrusion 3351 is engagingly received in the first receiving slot 271. Each sidewall 65 is slidably received between the side flange 251 and the bottom plate 21. The mounting block 631 extends out of the installation slot 231. A first end of the resilient member 80 abuts the mounting portion 61 with the mounting post 616 received therein. The positioning block 53 is inserted in the limiting hole 218. A second end of the resilient member 80 is received in the receiving hole 511. The installation block 52 is secured to the bottom plate 21 by a second screw 90. Thus, the operation member 30 is located between the positioning plate 27 and the limiting member 50, the limiting flange 551 abuts a top edge of the second flange 35, the positioning flange 275 abuts a top edge of the first flange 33, the blocking portion 351 is received in the sliding slot 57, and the blocking piece 3513 extends out of the sliding slot 57 and is aligned with the limiting slot 611. The hook 75 is engaged in the mounting slot 613. The resisting portion 73 abuts the resisting block 615, so that the sliding member 70 is secured to the mounting member 60. In this position, the resilient member 80 is in an initial state, the operation member 30 is in an unlocked position, and the mounting member 60 is in a movable position and is slidable relative to the panel 10.

When the operation member 30 is in the unlocked position and the mounting member 60 is in the movable position, the panel 10 can be secured to an enclosure (not shown). In assembly, a first end of the panel 10, which is opposite to the installation module 200, is rotatably positioned on the enclosure. When a second end of the panel 10 abuts the enclosure, the panel 10 is pressed downwards to slide the mounting member 60 towards the limiting member 50, and the limiting member 50 presses the resilient member 80 until the mounting block 631 is moved in the installation slot 231. In this position, the resilient member rebounds to slide the mounting member 60 away from the limiting member 50, and the mounting block 631 is locked into a locking hole defined in the enclosure. The operation piece 311 is pulled to elastically deform the positioning piece 335 until the positioning protrusion 3351 is aligned with the second positioning slot 272. In this position, the positioning piece 35 rebounds to engage the positioning protrusion 3351 in the second positioning slot 272, and the blocking piece 3513 and the limiting slot are staggered, so that the mounting member 60 is blocked from sliding by the blocking plane 3515. In this position, the operation member 30 is in a locked position, the mounting member 60 is in a secured position, and the panel assembly can be secured to the enclosure.

In disassembly, the operation member 30 is slid to the unlocked position, and each of the mounting member 60 and the sliding member 70 is slidable relative to the panel 10. The sliding member 70 is slid towards the limiting member 50 through the sliding plate 71, and the sliding member 70 slides the mounting member 60 towards the limiting member 50 to elastically deform the resilient member 80. The mounting block 631 is disengaged from the locking hole, and the panel assembly is rotatable for removal from the enclosure. The resilient member 80 is released, and the mounting member 60 is in the movable position.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A panel assembly, comprising a panel and an installation module configured to secure the panel to an enclosure, the installation module comprising:
a positioning member secured to the panel;
an operation member slidably mounted to the positioning member and comprising a blocking portion; and
a mounting member slidably mounted to the positioning member and defining a mounting slot;
wherein the operation member is slidable relative to the panel between an unlocked position and a locked position; when the operation member is in the unlocked position, the blocking portion is aligned with the mounting slot, and the mounting member is slidable relative to the panel to engage in a locking hole of the enclosure; and when the operation member is in the locked position, the blocking portion and the mounting slot are staggered, and the mounting member is blocked from sliding by the blocking portion.

2. The panel assembly of claim 1, wherein a sliding direction of the operation member is substantially perpendicular to a sliding direction of the mounting member.

3. The panel assembly of claim 1, wherein the mounting slot is substantially trapeziform.

4. The panel assembly of claim 1, wherein the installation module further comprises a limiting member secured to the positioning member and defining a sliding slot, and the blocking portion is slidably received in the sliding slot.

5. The panel assembly of claim 4, wherein the blocking portion comprises a blocking piece extending out of the sliding slot; when the operation member is in the unlocked position, the blocking piece is aligned with the mounting slot, the mounting member is slidable relative to the panel, the blocking piece is received in the mounting slot when the mounting member is moved towards the limiting member, and the blocking piece is disengaged from the mounting slot when the mounting member is moved away from the limiting member.

6. The panel assembly of claim 4, wherein the positioning member comprises a positioning plate, and the operation member is located between the positioning plate and the limiting member; the positioning plate defines a first positioning slot and a second positioning slot; when the operation member is in the unlocked position, the operation member is engaged in the first positioning slot; and when the operation member is in the locked position, the operation member is engaged in the second positioning slot.

7. The panel assembly of claim 6, wherein the operation member comprises an elastically deformable positioning piece, and a positioning protrusion protrudes from the positioning piece; when the operation member is in the unlocked position, the positioning protrusion is engaged in the first positioning slot; and when the operation member is in the locked position, the positioning protrusion is engaged in the second positioning slot.

8. The panel assembly of claim 4, wherein the operation member comprises an operation piece; the positioning member defines a positioning hole; the panel defines a through hole; the operation piece extends out of the positioning hole and the through hole; and the operation piece is operable to slide the operation member relative to the panel.

9. The panel assembly of claim 4, wherein the installation module further comprises a resilient member; the limiting member defines a receiving hole; the mounting member comprises a mounting portion and a mounting post, and the mounting slot is defined in the mounting portion; a first end of the resilient member abuts the mounting portion with the mounting post received therein, and a second end of the resilient member is received in the receiving hole.

10. The panel assembly of claim 1, wherein the installation module further comprises a sliding member secured to the mounting member, and when the sliding member is in the unlocked position, the sliding member is slidable to slide the mounting member relative to the panel.

11. A panel assembly, comprising a panel and an installation module configured to secure the panel to an enclosure, the installation module comprising:
a positioning member secured to the panel;
a limiting member secured to the positioning member;
an operation member slidably mounted to the positioning member and the limiting member and comprising a blocking portion;
a mounting member slidably mounted to the positioning member and defining a mounting slot; and
a resilient member mounted between the limiting member and the mounting member;
wherein the operation member is slidable relative to the panel between an unlocked position and a locked position; when the operation member is in the unlocked position, the blocking portion is aligned with the mounting slot, and the mounting member is slidable relative to the panel to engage in a locking hole of the enclosure; and when the operation member is in the locked position, the blocking portion and the mounting slot are staggered, and the mounting member is blocked from sliding by the blocking portion.

12. The panel assembly of claim 11, wherein a sliding direction of the operation member is substantially perpendicular to a sliding direction of the mounting member.

13. The panel assembly of claim 11, wherein the mounting slot is substantially trapeziform.

14. The panel assembly of claim 11, wherein the limiting member defines a sliding slot, and the blocking portion is slidably received in the sliding slot.

15. The panel assembly of claim 14, wherein the blocking portion comprises a blocking piece extending out of the sliding slot; when the operation member is in the unlocked position, the blocking piece is aligned with the mounting slot, the mounting member is slidable relative to the panel, the blocking piece is received in the mounting slot when the mounting member is moved towards the limiting member, and the blocking piece is disengaged from the mounting slot when the mounting member is moved away from the limiting member.

16. The panel assembly of claim 11, wherein the positioning member comprises a positioning plate, and the operation member is located between the positioning plate and the limiting member; the positioning plate defines a first positioning slot and a second positioning slot; when the operation member is in the unlocked position, the operation member is engaged in the first positioning slot; and when the operation member is in the locked position, the operation member is engaged in the second positioning slot.

17. The panel assembly of claim 16, wherein the operation member comprises an elastically deformable positioning piece, and a positioning protrusion protrudes from the positioning piece; when the operation member is in the unlocked position, the positioning protrusion is engaged in the first positioning slot; and when the operation member is in the locked position, the positioning protrusion is engaged in the second positioning slot.

18. The panel assembly of claim 11, wherein the operation member comprises an operation piece; the positioning member defines a positioning hole; the panel defines a through hole; the operation piece extends out of the positioning hole and the through hole; and the operation piece is operable to slide the operation member relative to the panel.

19. The panel assembly of claim 11, wherein the limiting member defines a receiving hole; the mounting member comprises a mounting portion and a mounting post, and the mounting slot is defined in the mounting portion; a first end of the resilient member abuts the mounting portion with the mounting post received therein, and a second end of the resilient member is received in the receiving hole.

20. The panel assembly of claim 11, wherein the installation module further comprises a sliding member secured to the mounting member, and when the sliding member is in the unlocked position, the sliding member is slidable to slide the mounting member relative to the panel.
